(19) United States
(12) Patent Application Publication
(10) Pub. No.: US 2011/0146784 A1
(43) Pub. Date: Jun. 23, 2011

(54) Photovoltaic device back contact

(75) Inventors: Pratima V. Addepalli, Monroe, MI (US); Oleh P. Karpenko, Perrysburg, OH (US); Thomas W. Shields, Perrysburg, OH (US)

(73) Assignee: First Solar, Inc., Perrysburg, OH (US)

(21) Appl. No.: 12/970,793

(22) Filed: Dec. 16, 2010

Related U.S. Application Data
(60) Provisional application No. 61/288,065, filed on Dec. 18, 2009.

(51) Int. Cl. H01L 31/0224; H01L 31/0272

(52) U.S. Cl. 136/256; 438/94; 257/E31.008

(57) ABSTRACT

A method for manufacturing a photovoltaic device may include depositing a semiconductor absorber layer on a substrate, depositing a molybdenum in the presence of a nitrogen to form a molybdenum nitride in contact with the semiconductor absorber layer, and doping the molybdenum nitride with a copper dopant.

### CLAIM FOR PRIORITY

This application claims priority under 35 U.S.C. §119(e) to U.S. Provisional Patent Application Ser. No. 61/288,065 filed on Dec. 18, 2009, which is hereby incorporated by reference.

### TECHNICAL FIELD

The present invention relates to photovoltaic devices and methods of production.

### BACKGROUND

Photovoltaic devices can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity.

Photovoltaic devices can also contain one or more transparent conductive oxide layers, which are also often conductors of electrical charge.

### DESCRIPTION OF DRAWINGS

FIG. 1 is a schematic of a photovoltaic device having multiple layers.

FIG. 2 is a schematic of a photovoltaic device having multiple layers.

### DETAILED DESCRIPTION

Photovoltaic modules can include one or more layers created adjacent to a substrate. Layers can be created by forming or depositing material adjacent to the substrate. For example, a photovoltaic module may contain a semiconductor absorber layer deposited over a semiconductor window layer. Each layer may in turn include more than one layer or film. Additionally, each layer can cover all or a portion of the device and/or all or a portion of the layer or substrate underlying the layer. For example, a “layer” can mean any amount of any material that contacts all or a portion of a surface.

A photovoltaic device can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power.

Photovoltaic devices can be formed on optically transparent substrates, such as glass. Because glass is not conductive, a transparent conductive oxide (TCO) layer is typically deposited between the substrate and the semiconductor bi-layer to serve as a front contact. A metal layer can be deposited onto the p-type absorber layer to serve as a back contact. The front and back contacts can serve as electrodes for the photovoltaic device. A variety of materials are available for the metal layer, including, but not limited to molybdenum, aluminum, chromium, iron, nickel, titanium, vanadium, manganese, cobalt, zinc, ruthenium, tungsten, silver, gold, and platinum. Molybdenum functions particularly well as a back contact metal due to its relative stability at processing temperatures and low contact resistance. The electrical energy produced as a percentage of the incident solar energy can be increased as a result of incorporating nitrogen into the back contact metal.

A method for manufacturing a photovoltaic device may include depositing a semiconductor absorber layer on a substrate, depositing a molybdenum in the presence of a nitrogen to form a molybdenum nitride in contact with the semiconductor absorber layer, and doping the molybdenum nitride with a dopant. The dopant can include a p-type dopant. The dopant can include copper, silver, or gold, or any other suitable material. The molybdenum nitride may include a stoichiometric nitride. The molybdenum nitride may include a non-stoichiometric nitride. The step of depositing molybdenum in the presence of nitrogen gas can include depositing molybdenum in an environment including more than 10% nitrogen gas. The environment can include more than 30% nitrogen gas. The environment can include more than 50% nitrogen gas. The environment can include more than 70% nitrogen gas. The environment can include 60% to 90% nitrogen gas. The environment can include 70% to 80% nitrogen gas.

The method can include depositing a chromium layer on the semiconductor absorber layer prior to depositing a molybdenum. The method can include depositing an aluminum layer on the molybdenum nitride. The method may include depositing the semiconductor absorber layer on a semiconductor window layer. The semiconductor absorber layer can include a cadmium telluride layer. The semiconductor window layer can include a cadmium sulfide layer.

The method may include depositing the semiconductor window layer on a transparent conductive oxide stack. The transparent conductive oxide stack can include a buffer layer on a transparent conductive oxide layer. The transparent conductive oxide layer can be positioned on one or more barrier layers. Each of the one or more barrier layers may include a silicon nitride, aluminum-doped silicon nitride, silicon oxide, aluminum-doped silicon oxide, boron-doped silicon nitride, phosphorous-doped silicon nitride, silicon oxide-nitride, tin oxide, or any combination thereof. The method may include depositing the transparent conductive oxide stack on the substrate. The substrate may include a glass. The glass may include a soda-lime glass. The transparent conductive oxide layer may include a cadmium stannate. The buffer layer may include a zinc tin oxide, tin oxide, zinc oxide, zinc magnesium oxide, or combinations thereof. The method may include annealing the transparent conductive oxide stack. The method may include depositing a back support on the molybdenum nitride.

A photovoltaic device may include a contact layer on a semiconductor absorber layer. The contact layer can include a crystalline molybdenum nitride including a p-type dopant. The dopant can include copper, silver, or gold, or any other suitable material. The molybdenum nitride may include a stoichiometric nitride. The molybdenum nitride may include a non-stoichiometric nitride. The molybdenum nitride may be formed in an environment including more than 10% nitrogen gas. The environment can include more than 30% nitrogen gas. The environment can include more than 50% nitrogen gas. The environment can include more than 70% nitrogen gas. The environment can include between 60% and 90% nitrogen gas. The environment can include between 70% and 80% nitrogen gas.

The photovoltaic device may include a chromium layer on the semiconductor absorber layer. The photovoltaic device can include an aluminum layer on the molybdenum nitride. The photovoltaic device may include a semiconductor window layer. The semiconductor absorber layer can be positioned on the semiconductor window layer. The semiconductor window layer can include a cadmium sulfide layer. The semiconductor absorber layer can include a cadmium telluride layer. The photovoltaic device can include a transparent conductive oxide stack. The transparent conductive oxide stack can include a buffer layer on a transparent conductive oxide layer. The transparent conductive oxide layer can be positioned on one or more barrier layers. The semiconductor window layer can be positioned on the transparent conductive oxide stack. Each of the one or more barrier layers may include a silicon nitride, aluminum-doped silicon nitride, silicon oxide, aluminum-doped silicon oxide, boron-doped silicon nitride, phosphorous-doped silicon nitride, silicon oxide-nitride, tin oxide, or combinations. The photovoltaic device may include a substrate, where the transparent conductive stack is positioned on the substrate. The substrate may include a glass. The glass may include a soda-lime glass. The transparent conductive oxide layer may include a cadmium stannate. The buffer layer may include a zinc tin oxide, tin oxide, zinc oxide, zinc magnesium oxide, or combinations thereof. The photovoltaic device may include a back support on the molybdenum nitride.

Incorporation of nitrogen into the back contact can be achieved by using a nitrogen gas supply along with argon in the sputtering system, or by using a premixed nitrogen-argon gas cylinder. Similar results can be achieved by using a compound target that is mixed with desired levels of nitrogen and sputtered argon or argon/nitrogen ambient. The range of nitrogen, for a nitrogen and argon mixed ambient, can be as low as 1% to 2%, to as high as 50%, or 100% with no argon. The amount of nitrogen gas in the deposition environment can be more than 10%, more than 30%, more than 50%, and more than 70%. The amount of nitrogen gas in the deposition environment can be between 60% and 90%. The amount of nitrogen gas in the deposition environment can be between 70% and 80%. For example, the amount of nitrogen gas can be 75%. The level of nitrogen used in the mixture affects the amount of nitrogen incorporated into the metal film. One can thus deposit a metal layer with various levels of nitrogen, such as a molybdenum nitride layer. Metal deposition can be carried out without any intentional heating of the substrate. Substrate heating, however, is known to affect film properties including incorporation of gas-phase impurities such as nitrogen.

Nitrogen can be incorporated into a contact metal to form a molybdenum nitride back contact. A crystalline high work function molybdenum contact can be generated by changing the gas composition and deposition parameters during metal deposition for efficiency and reliability improvements. The molybdenum nitride can be modified from its existing amorphous/nano-crystalline phase to a cubic molybdenum nitride, for example, a Mo₂N or a Mo₃N₂. Higher concentrations of nitrogen gas can be incorporated during the deposition process to transform molybdenum from an amorphous state to a crystalline state. Molybdenum nitride back contacts with increased nitrogen content demonstrated an increase in work function of 4% or greater. The improved molybdenum nitride contacts also exhibited higher efficiency, for example, 15% or greater, as well as significant improvement in reverse current overload pass rate and back contact stability, over conventional modules. The molybdenum nitride can be doped with a p-type dopant to achieve higher efficiency, and to help retain the open circuit voltage component of the I(V) curve. For example, the molybdenum nitride can be doped with copper, silver, or gold, or any other suitable material.

The MoNx deposition process can be preceded by either an aqueous- or a plasma-based dry process for dopant application. The dopant addition can also happen during the MoNx deposition with suitable precursors incorporated within the MoNx contact and serving as an infinite source. The dopants are subsequently activated via a thermal activation step that can facilitate the creation of a p+CdTe region. Materials such as Cu, Au, Ag, P, N, Sb can be used as dopants for CdTe.

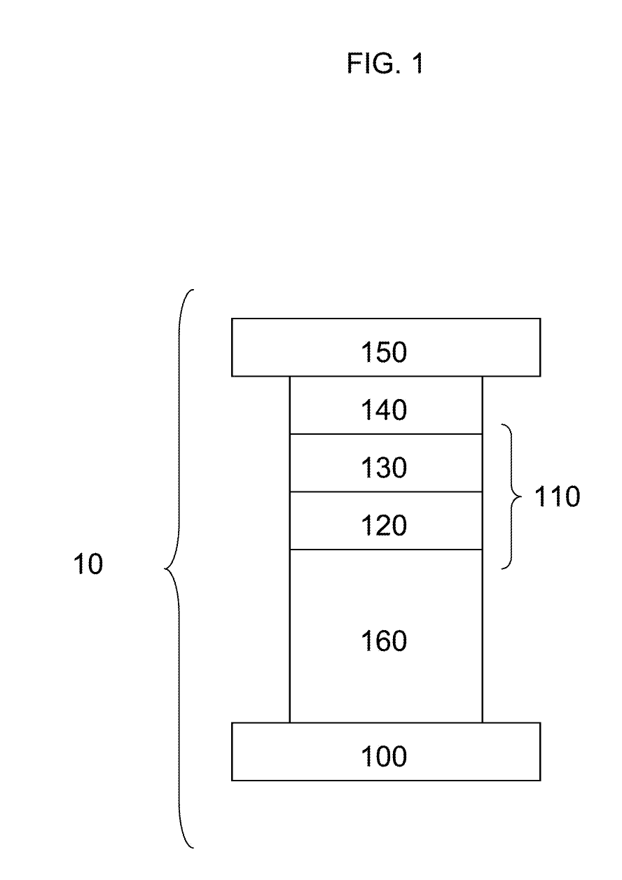

Referring to FIG. 1, a photovoltaic device 10 can include a back contact layer 140 deposited over a semiconductor bi-layer 110. Back contact layer 140 may include a molybdenum, and may be deposited in the presence of a nitrogen gas or a nitrogen-argon gas mix. The amount of nitrogen gas in the environment can be more than 10%, more than 30%, more than 50%, and more than 70%, and any other suitable amount of nitrogen gas. The amount of nitrogen gas in the environment can be 60% to 90%. The amount of nitrogen gas in the environment can be 70% to 80%. Back contact layer 140 may include a molybdenum nitride. The molybdenum nitride may be doped with a p-type dopant during deposition to increase the efficiency of the device. Examples of suitable dopants are dopants including copper, silver, or gold. Back contact layer 140 may include a molybdenum nitride with increased nitrogen content. The increased nitrogen content can transform the molybdenum from an amorphous structure into a crystalline structure. The increase in nitrogen content can also result in a higher work function for back contact layer 140, as well as improved diffusion barrier properties. For example, by increasing the nitrogen content to more than 70%, an increase in work function of more than 4% or more can be realized. A p-type dopant such as copper may be incorporated into the deposition process, resulting in a doped molybdenum nitride contact. The copper dopant can be present in any suitable concentration. For example, the copper dopant can be present in a concentration of about 1×10¹⁷ to about 1×10²⁰. The amount of dopant can be changed to yield a higher efficiency. The amount of dopant can be increased to yield a higher efficiency.

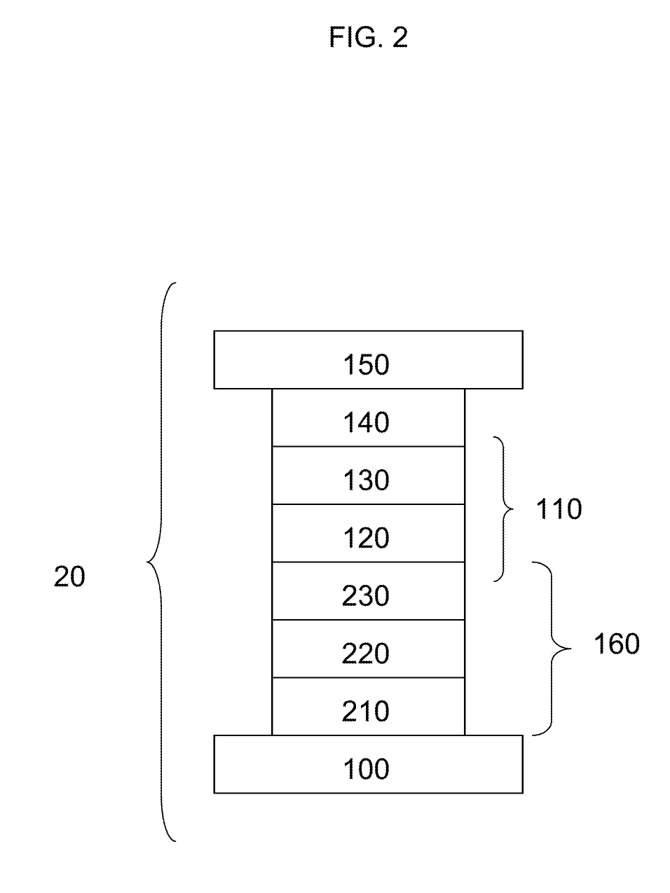

Back contact layer 140 can be deposited directly on semiconductor absorber layer 130, which along with semiconductor window layer 120, can be part of semiconductor bi-layer 110. Back contact layer 140 can be deposited as a molybdenum in the presence of a nitrogen gas to obtain a molybdenum nitride. Back contact layer 140 can be deposited using any suitable deposition technique, including, for example, sputtering. Back contact layer 140 can have any a suitable thickness, for example, greater than 10 A, greater than 20 A, greater than 50 A, greater than 100 A, greater than 250 A, greater than 500 A, less than 2000 A, less than 1500 A, less than 1000 A, or less than 750 A. In continuing reference to FIG. 2, a back support 150 can be deposited adjacent to back contact layer 140. Back support 150 can include a glass, for example, a soda-lime glass. Semiconductor bi-layer 110 can be deposited on transparent conductive oxide stack 160, which may include a transparent conductive oxide layer. Transparent conductive oxide stack 160 may be deposited on substrate 100, which may include any suitable substrate material, including a glass, for example, a soda-lime glass.

Referring to FIG. 2, a photovoltaic device 20 can include a transparent conductive oxide layer 220 adjacent to substrate 100. Transparent conductive oxide layer 220 can be deposited adjacent to substrate 200, or the layers can be pre-fabricated. Transparent conductive oxide layer 220 can be deposited using any known deposition technique, including, for example, sputtering. Transparent conductive oxide layer 220 can include any suitable material, including cadmium stannate, tin oxide, and indium tin oxide. Transparent conductive oxide layer 220 can be part of transparent conductive oxide stack 160. Transparent conductive oxide stack 160 can include a barrier layer 210 and a buffer layer 230. Transparent conductive oxide layer 220 can be deposited adjacent to barrier layer 210 to form transparent conductive oxide stack 210. Transparent conductive oxide layer 220 can be deposited using any known deposition technique, including, for example, sputtering. Barrier layer 210 can include any suitable barrier material, including, for example, a silicon nitride, aluminum-doped silicon nitride, silicon oxide, aluminum-doped silicon oxide, boron-doped silicon nitride, phosphorous-doped silicon nitride, silicon oxide-nitride, tin oxide, or any combinations thereof. Buffer layer 230 can be deposited adjacent to transparent conductive oxide layer 220 to form transparent conductive oxide stack 160. Buffer layer 230 can be deposited using any known deposition technique, including sputtering. Buffer layer 230 can include any suitable material, including, for example, a zinc tin oxide, tin oxide, zinc oxide, zinc magnesium oxide, or any combinations thereof. Transparent conductive oxide stack 210 can be annealed prior to the subsequent deposition of semiconductor bi-layer 110.

Transparent conductive oxide stack 210 can be manufactured using a variety of deposition techniques, including, for example, low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis. Each deposition layer can be of any suitable thickness, for example in the range of 1 to 5000 A.

Photovoltaic devices/modules fabricated using the methods and apparatuses discussed herein may be incorporated into one or more photovoltaic arrays. The arrays may be incorporated into various systems for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the module to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method for manufacturing a photovoltaic device, the method comprising:
depositing a semiconductor absorber layer on a substrate;
depositing molybdenum in the presence of a nitrogen gas to form a molybdenum nitride in contact with the semiconductor absorber layer; and
doping the molybdenum nitride with a p-type dopant.

2. The method of claim 1, wherein the dopant comprises copper, silver, or gold.

3. The method of claim 1, wherein the molybdenum nitride comprises a stoichiometric or non-stoichiometric nitride.

4. The method of claim 1, wherein the step of depositing molybdenum in the presence of nitrogen gas comprises depositing molybdenum in an environment comprising more than 10% nitrogen gas or less than 80% nitrogen gas.

5. The method of claim 1, further comprising:
depositing a chromium layer on the semiconductor absorber layer prior to depositing a molybdenum; and
depositing an aluminum layer on the molybdenum nitride.

6. The method of claim 1, further comprising depositing the semiconductor absorber layer on a semiconductor window layer, the semiconductor absorber layer comprising a cadmium telluride layer, and the semiconductor window layer comprising a cadmium sulfide layer.

7. The method of claim 6, further comprising depositing the semiconductor window layer on a transparent conductive oxide stack, wherein the transparent conductive oxide stack comprises a buffer layer on a transparent conductive oxide layer, wherein the transparent conductive oxide layer is positioned on one or more barrier layers, wherein each of the one or more barrier layers comprises a material selected from the group consisting of silicon nitride, aluminum-doped silicon nitride, silicon oxide, aluminum-doped silicon oxide, boron-doped silicon nitride, phosphorous-doped silicon nitride, silicon oxide-nitride, and tin oxide.

8. The method of claim 7, further comprising depositing the transparent conductive oxide stack on the substrate.

9. The method of claim 7, wherein the transparent conductive oxide layer comprises a cadmium stannate.

10. The method of claim 7, wherein the buffer layer comprises a material selected from the group consisting of zinc tin oxide, tin oxide, zinc oxide, and zinc magnesium oxide.

11. The method of claim 7, further comprising annealing the transparent conductive oxide stack.

12. A photovoltaic device, comprising:
a contact layer on a semiconductor absorber layer, the contact layer comprising a crystalline molybdenum nitride including a p-type dopant.

13. The photovoltaic device of claim 12, wherein the dopant comprises copper, silver, or gold.

14. The photovoltaic device of claim 12, wherein the molybdenum nitride comprises a stoichiometric or non-stoichiometric nitride.

15. The photovoltaic device of claim 12, further comprising:
a chromium layer on the semiconductor absorber layer; and
an aluminum layer on the molybdenum nitride.

16. The photovoltaic device of claim 12, further comprising a semiconductor window layer, wherein the semiconductor absorber layer is positioned on the semiconductor window layer, and wherein the semiconductor window layer comprises a cadmium sulfide layer, and the semiconductor absorber layer comprises a cadmium telluride layer.

17. The photovoltaic device of claim 16, further comprising a transparent conductive oxide stack comprising a buffer layer on a transparent conductive oxide layer, wherein the transparent conductive oxide layer is positioned on one or more barrier layers, wherein the semiconductor window layer is positioned on the transparent conductive oxide stack, wherein each of the one or more barrier layers comprises a material selected from the group consisting of silicon nitride, aluminum-doped silicon nitride, silicon oxide, aluminum-doped silicon oxide, boron-doped silicon nitride, phosphorous-doped silicon nitride, silicon oxide-nitride, and tin oxide.

18. The photovoltaic device of claim 17, further comprising a substrate, wherein the transparent conductive stack is positioned on the substrate.

19. The photovoltaic device of claim 17, wherein the transparent conductive oxide layer comprises a cadmium stannate.

20. The photovoltaic device of claim 17, wherein the buffer layer comprises a material selected from the group consisting of zinc tin oxide, tin oxide, zinc oxide, and zinc magnesium oxide.
